(19) United States
(12) Patent Application Publication
(10) Pub. No.: US 2005/0270186 A1
(43) Pub. Date: Dec. 8, 2005

(54) Specified index method for abstract syntax notation one encoding systems

(76) Inventor: Tai-Hung Lin, Taipei (TW)

Correspondence Address: Yi-Wen Tseng, 4331 Stevens Battle Lane, Fairfax, VA, 22033, US

(21) Appl. No.: 10/861,348

(22) Filed: Jun. 7, 2004

(51) Int. Cl. H03M 7/00

(52) U.S. Cl. 341/50

(57) ABSTRACT

This invention applies a specified index method for Abstract Syntax Notation One (ANS.1) encoding systems. Its procedure includes receiving input data, adding specified indices to the data and determining if the data consists of an omitted optional item or an omitted default item. If so, it modifies the specified index of the optional/default item. It then adds, updates, inserts or deletes the data directly. And it adjusts the code of the modified data according to the specified index, and outputs the newly encoded data. This invention can be used in the electronic/digital signature applications, such as cosigns or countersigns which need timely encoding data inputs from multiple entities. The new method can save the memory space and speed up the processing time since it does not need completely decoding and encoding the whole input data.

### BACKGROUND OF THE INVENTION

This invention relates a specified index method for Abstract Syntax Notation One (ASN.1) encoding systems, which can directly modify an encoded ASN.1 data and produce newly adjusted code. The modification needs focusing only on the target items and does not need completely decoding the input data and nor completely encode all data after modification.

Since the implementation of digital signatures, the systems that request for electronic/digital signatures become very popular. However, inefficiency of the conventional ASN.1 coding/decoding method has hindered applications that require multiple exchanges of signatures. The completely coding/decoding the ASN.1 data in the conventional methods not only takes extra processing time but also consumes additional memory/disk space to store the decoded data. This slows down the applications of cosign and countersign systems. For each incoming data source entity, a conventional method comprises the following steps: (1). Completely decode ASN.1 data. (2). Add, update, insert or delete data. (3). Completely encode the modified data.

FIG. 1 illustrates the process flow of a conventional coding/decoding method. The first step is receiving input data (Step 100). The input data of a conventional method is a digital serial data in a linear octet string. Basically, this data is generated from a tree-structure like information. In a conventional method, in order to encoding the data, it requires to completely decoding the whole data (Step 110) to recover its original tree-structure like format. It then conducts the data modification step (Step 120) which consists of adding, updating, inserting or deleting the input data. It still needs to conduct completely encoding step (Step 130) before output the encoded data (Step 140).

In general, the more complicated tree structure of the original format is, the more memory/disk space for decoded data is needed. It also takes longer processing time. Based on these drawbacks, the inventor has conducted careful studies and analyses to propose this method. This invention provides a better and reasonable design which can eliminates above drawbacks in a conventional method.

### BRIEF SUMMARY OF THE INVENTION

This invention is to apply a specified index method for the ASN.1 encoding systems; therefore to achieve the advantages as follows. (1). To reduce the memory/disk space needed for encoding. (2). To speed up the encoding time. (3). To make the encoding method easy to use.

This invention does not duplicate all the original data formats and save them in the computer storage during decoding process. It only marks the specified indices on all the nodes of the original data for decoding. During the encoding, it needs not duplicate and save all the original data either. It can directly encode the node of the original data that has been modified based on the specified index. Furthermore, it needs not to know the specified indices of the nodes that have not changed. It only needs to know the target items that are to be modified. This reduces problems that may occur during access various encoding systems.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These, as well as other features of the present invention, will become apparent upon reference to the drawings wherein:

FIG. 1 depicts the process flow of a conventional method for an ASN.1 coding/decoding system.

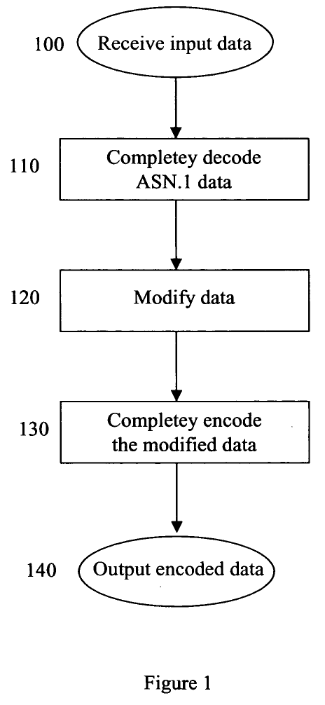

FIG. 2 depicts the process flow of the present invention for an ASN.1 encoding system.

FIG. 3 illustrates an example that is applied in a conventional method for an ASN.1 coding/decoding system.

FIG. 4 illustrates an example that is applied in the present invention for an ASN.1 encoding system.

### DETAILED DESCRIPTION OF THE INVENTION

To provide a further understanding of features and technical contents of this invention for the review committee, please refer to the following detailed descriptions and attached figures. The figures are only for references and illustration purpose, which should not limit the scope of this invention.

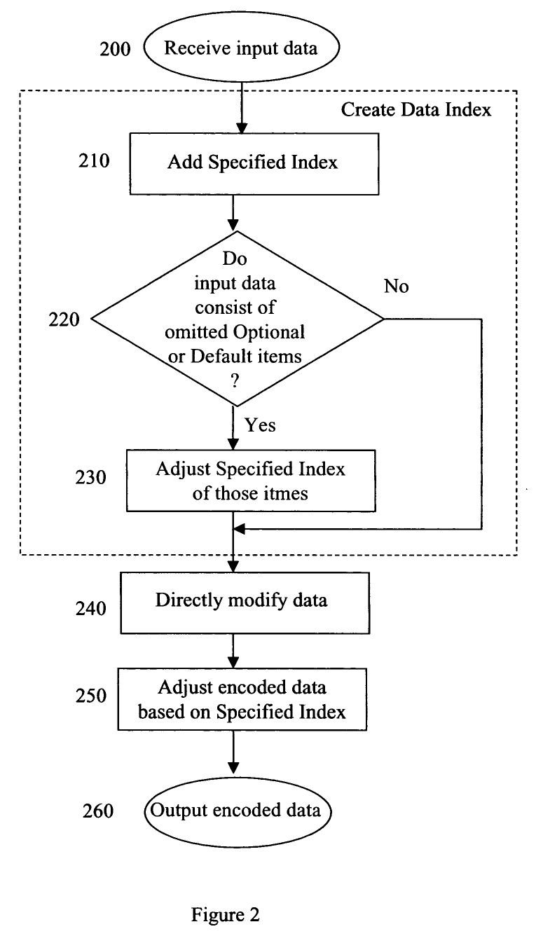

FIG. 2 illustrates a process flow of this invention. This invention applies the specified index method for the ASN.1 encoding systems. The process starts with a step of receiving input data (Step 200). The input data received is the same as the input data for the conventional encoding systems. That is a linear octet string. The process then adds specified index to the input data (Step 210). The next step is to determine whether the input data consists of an omitted optional item or an omitted default item (Step 220). If so, the process adjusts the specified indices of those items to include the omitted items (Step 230). Thus, the data index has been created via Steps 210 to 230. The process can directly modify the data (Step 240). The modification consists of command ‘add’, ‘update’, ‘insert’ and ‘delete’. It then adjusts encoded data based on the specified index only for the modified items (Step 250) and output the encoded data (Step 260).

This invention can improve the efficiency of encoding ASN.1 data and make ASN.1 data easy to use. The new method does not need completely decoding and encoding all data, thus it can save computer process time and memory space.

As shown in FIG. 2, after receiving the input data, this method first creates the data index, and uses this index to modify data. It then adjusts the code during encoding. The input format of this method is the same as the conventional method. The input data is a linear octet string. Basically, this data has a tree-like structure. In order to encoding a data, the conventional method needs first completely decoding the data to recovery its original tree structure format. To avoid completely decoding, this method replaces the process of recovering its format by creating a data index. The contents of a data index are as follows: (1). The position of an item in the original data. (2). The length of data item. (3). Index of tree-structure. (4). Information regarding the modification for data item.

The purpose of creating data index is to avoid completely decoding. Contents (1) and (2) provide the position and length of an item in the original data, thus they can be used during decoding without duplicating data. When item needs to be modified, contents (3) and (4) provide the location of a data in a tree structure and include the modification action in a data index.

The creating data index step includes adjusting the specified indices of the optional items or the default items. According to the ASN.1 definition, when an optional item is not used, the code does not need to include this optional item. However, during the encoding, the omitted optional item may be modified. Thus, the omitted optional items are added in the data indices. Similarly, according to ASN.1 definition, when the value of a default item equals the default value, the code does not need to include this default item. However, during the encoding, the omitted default item may be modified. Thus, the omitted default items are also added in the data indices.

The modification of data includes adding, updating, inserting or deleting data.

This invention includes an ASN.1 data definition loader that has the following features: (1). The loader is used to create a special data catalog to clearly list various data tags. The data tags include implicit tag and/or explicit tag. The loader also lists the types of data structures which include SET/SETOF/SEQUENCE/SEQUENCE OF/INSTANCE OF/CHOICE, etc. It lists ASN.1 special properties which include OPTIONAL/DEFAULT/ANY, etc. (2). The loader can be accessed anytime by ASN.1 encoding/decoding program. (3). The ASN.1 encoding/decoding program does not need to be modified when some data structure changes are made.

According to the definition of ASN.1, the SET OF data structure may contain any number of similar sub-items. Before encoding the data again, these sub-items may be deleted. The addition of a sub-item is noted in its parent item. There is no limit on the number of sub-items to be added.

According to the definition of ASN.1, the SEQUENCE OF or INSTANCE OF data structures may contain any number of similar sub-items. Before encoding the data again, these sub-items may be deleted. The insertion of a sub-item is noted in the previous sub-item. There is no limit on the number of sub-items to be inserted.

According to the definition of ASN.1, the SET data structure may contain a fixed number of pre-defined sub-items. Before encoding the data again, these sub-items may be updated. If they are noted as the optional items or the default items, the items may be deleted.

According to the definition of ASN.1, the SEQUENCE data structure may contain a fixed number of pre-defined sub-items. Before encoding the data again, these sub-items may be updated. If they are noted as the optional items or the default items, the items may be deleted.

According to the definition of ASN.1, the CHOICE data structure contains a single item. Before encoding the data again, this sub-item may be updated. The name and tag of this sub-item may also be updated.

According to the definition of ASN.1, a primitive data type contains a single item. Before encoding the data again, the item may be updated. Also, the ANY data type may be updated before encoding it again. The tag of this item may be updated.

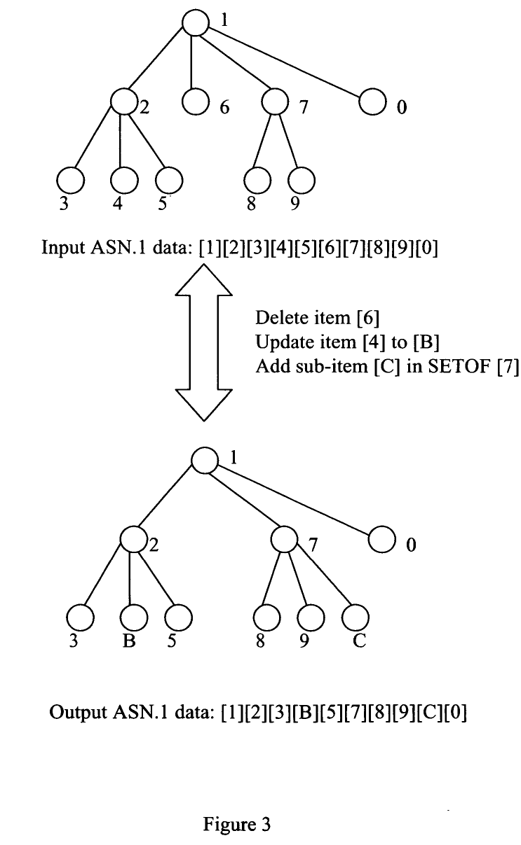

FIG. 3 illustrates an example that is applied in a conventional method for ASN.1 coding/decoding system. The input data with a tree-like structure received is as follows:
[1][2][3][4][5][6][7][8][9][0]

A conventional method needs first completely decoding the data to recover its original tree structure as follows:
[1]-[2][6][7][0]
[2]-[3][4][5]
[7]-[8][9]

It then conducts the modifications of the data, such as:
(a). Delete item [6]: [1]-[2][6][7][0]=>[1]-[2][7][0]
(b). Update item [4] to become [B]: [2]-[3][4][5]=>[2]-[3][B][5]
(c). Add new sub-item [C] in SETOF item [7]: [7]-[8][9]=>[7]-[8][9][C]

In the end, it needs to completely encode the data with the new tree structure:
[1][2][3][B][5][7][8][9][C][0]

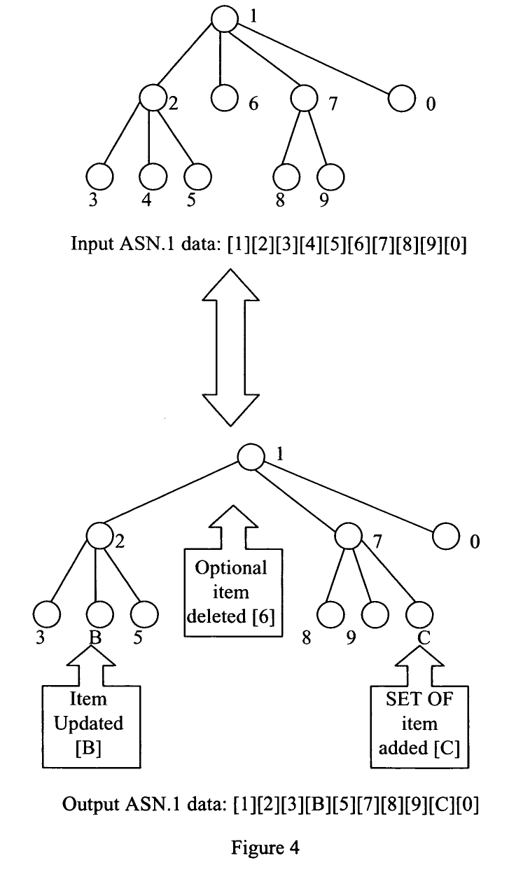

FIG. 4 illustrates an example that is applied in this invention. The same input data is received in this invention:
[1][2][3][4][5][6][7][8][9][0]

In order to avoiding the need of completely decoding, this invention first creates data index instead of creating tables. It adds the specified index at each node. In addition to the item's position and length in the original data and index of a tree structure, it also adds the modification information in the data index. For item [6], it marks “optional item deleted”. For item [4], it marks “item updated [B]”. For adding new item [C], it marks in the parent of item [C], i.e., the SET OF item [7], “SETOF item added [C]”.

It then directly modifies the data and adjusts the code based on the specified index. It outputs the modified code as follows:
[1][2][3][B][5][7][8][9][C][0]

This disclosure provides exemplary embodiments of the present invention. The scope of this disclosure is not limited by these exemplary embodiments. Numerous variations, whether explicitly provided for by the specification or implied by the specification, such as variations in shape, structure, dimension, type of material or manufacturing process may be implemented by one of skill in the art in view of this disclosure.

1. A specified index method for an Abstract Syntax Notation One (ASN.1) encoding system, comprises the steps of:
a. receiving input data;
b. adding an specified index and creating a data index;
c. conducting data modifications including adding, updating, inserting and/or deleting the data;
d. adjusting the data based on the specified index; and
e. outputting the data.

2. The method as claimed in claim 1, wherein the received input data in the step (a) is a linear octet string.

3. The method as claimed in claim 1, wherein the step (b) further comprising the following steps in creating the data index:
adjusting the specified index of optional items and default items; and
adding omitted optional items and omitted default items for future updates.

4. The method as claimed in claim 1, wherein the data index in the step (b) includes a position of an item in the data, a length of an item data, an index of a tree structure thereof and modification remarks of an item.

5. The method as claimed in claim 1, wherein a SET OF data structure in the step (c) includes any number of similar sub-items which can be deleted or added before encoding again, and an added sub-item is noted in a parent item thereof so that there is no limit on the number of sub-items to be added.

6. The method as claimed in claim 1, wherein a SEQUENCE OF or an INSTANCE OF data structure in the step (c) includes any number of similar sub-items, which can be deleted or inserted before encoding again, and an inserted sub-item is noted in a previous sub-item so that there is no limit on the number of sub-items to be inserted.

7. The method as claimed in claim 1, wherein a SET or a SEQUENCE data structure in the step (c) includes a fixed number of pre-defined sub-items which can be updated before encoding again and if which is an optional item or a default item, which can be deleted.

8. The method as claimed in claim 1, wherein a CHOICE data structure in the step (c) includes a single item which can be updated before encoding again and a name and a tag thereof can also be updated.

9. The method as claimed in claim 1, where a primitive data type in the step (c) includes a single item which can be updated before encoding again.

10. The method as claimed in claim 1, where a ANY data type in the step (c) can be updated before encoding again and a tag thereof can also be updated.
